(19) United States
(12) Patent Application Publication
(10) Pub. No.: US 2026/0020202 A1
(43) Pub. Date: Jan. 15, 2026

(54) DISPLAY DEVICE WITH THERMAL PAD

(71) Applicant: Yong Wook SHIN, Hwaseong-si (KR)

(72) Inventor: Yong Wook SHIN, Hwaseong-si (KR)

(21) Appl. No.: 18/769,330

(22) Filed: Jul. 10, 2024

(51) Int. Cl. H05K 7/20

(52) U.S. Cl. CPC H05K 7/20963

(57) ABSTRACT

A display device includes: a main board having at least one IC chip on a first side and at least one IC chip on a second side; a first thermal pad attached to the at least one IC chip provided on the first side of the main board; a second thermal pad attached to the at least one IC chip on the second side of the main board; a first aluminum plate provided on the first thermal pad; a second aluminum plate provided on the second thermal pad, wherein the first aluminum plate is configured to be in contact with a specific area of a predetermined area of the rear housing of the enclosure, wherein the second aluminum plate is configured to be in contact with a touchscreen panel.

### BACKGROUND

The present disclosure relates to a display device, and, in detail, a display device with thermal pad.

In elevators and various other outdoor spaces, display devices are installed that output advertising contents or informational contents.

These display devices are always in operation, and the problem is that they heat up due to prolonged operation. This heat can lead to failures or malfunctions, and in some cases, they are left broken and unable to perform their required functions.

In the past, heat sinks have been heavily utilized, but heat sinks are very bulky and not efficient for wall-mounted display devices.

On the other hand, various measures are being taken to manage the heat of display devices, but there is no proper plan to optimize the heat generation method according to the operating state of the display device. The heat management of display devices is based on universal standards regardless of the operating state of the display device.

In particular, the display device in an elevator only works when a person enters the elevator, and if a person frequently enters and exits the elevator, it becomes more difficult to manage the heat of the display device. In other words, individualized heat dissipation measures cannot be taken according to the operating environment of the display device.

### SUMMARY

An objective of the present disclosure is to provide a display device with thermal pad.

A display device with thermal pad according to the objectives of the present disclosure described above may be configured to include: a main board having at least one IC chip on a first side; a thermal pad having a first thermal pad attached to the at least one IC chip provided on the first side of the main board.

The main board is configured to have at least one IC chip on a second side.

The display device may be configured to further include a second thermal pad attached to the at least one IC chip provided on the second side of the main board.

According to the display device with thermal pad, it is configured to form a high conductivity silicon thermal pad on a group of IC chips of a main board, and to attach an aluminum plate to the thermal pad, so that heat generated by the IC chips can be dissipated with high efficiency to prevent failure or malfunction of the IC chips.

In particular, by configuring the aluminum plate to interview the metal housing at the rear of the housing, it has the effect of allowing heat to be easily dissipated to the outside through the metal housing.

Furthermore, since the aluminum plate is configured to be in contact with metal housing on the backside of the enclosure of the housing, heat can be easily dissipated through the metal housing to the outside.

In addition, the sides of the thermal pad and aluminum plate are configured to have insulating bands wrapped around them, so that the heat transferred to the thermal pad and aluminum plate can be dissipated through the metal housing to the outside, rather than being retained inside the housing.

And the temperature sensor measures the temperature of each IC chip, and the sub-board is configured to control the operation of the main board so that the temperature is maintained below a predetermined standard, which has the effect of preventing the main board from overheating.

On the other hand, the sub-board is configured to analyze the operating state of the main board and calculate the area of the thermal pad that enables efficient heat dissipation according to the operating state of the display device, thereby having the effect of taking heat dissipation measures necessary for the individual operating state of the display device.

### BRIEF DESCRIPTION OF THE DRAWINGS

FIG. 1 is a side view of a display device with thermal pad according to one embodiment of the present disclosure.

FIG. 2 is a side perspective view of a display device with thermal pad according to one embodiment of the present disclosure.

FIG. 3 is an interior perspective view of a display device with thermal pad according to one embodiment of the present disclosure.

FIG. 4 is a block configuration diagram of a sub-board according to one embodiment of the present disclosure.

### DETAILED DESCRIPTION

The present disclosure may be modified in various ways and implemented by various exemplary embodiments, so that specific exemplary embodiments are shown in the drawings and will be described in detail in the detailed description for implementing the present disclosure. However, it is to be understood that the present disclosure is not limited to the specific exemplary embodiments, but includes all modifications, equivalents, and substitutions included in the spirit and the scope of the present disclosure. Similar reference numerals are assigned to similar components in the following description of drawings.

Terms used in the specification, ‘first’, ‘second’, ‘A’, ‘B’, etc., may be used to describe various components, but the components are not to be construed as being limited to the terms. The terms are used only to distinguish one component from another component. For example, the first component may be named the second component, and vice versa, without departing from the scope of the present disclosure. The term ‘and/or’ includes a combination of a plurality of relevant items or any one of a plurality of relevant terms.

It is to be understood that when one element is referred to as being “connected to” or “coupled to” another element, it may be connected directly to or coupled directly to another element or be connected to or coupled to another element, having the other element intervening therebetween. On the other hand, it is to be understood that when one element is referred to as being “connected directly to” or “coupled directly to” another element, it may be connected to or coupled to another element without the other element intervening therebetween.

The terms used herein are used only for the purpose of describing particular embodiments and are not intended to limit the present disclosure. Singular forms are intended to include plural forms unless the context clearly indicates otherwise. It will be further understood that the terms “comprises” or “have” used in this specification, specify the presence of stated features, steps, operations, components, parts, or a combination thereof, but do not preclude the presence or addition of one or more other features, numerals, steps, operations, components, parts, or a combination thereof.

Unless defined otherwise, it is to be understood that all the terms used in the specification including technical and scientific terms have the same meanings as those that are understood by those who skilled in the art. It will be further understood that terms defined in dictionaries that are commonly used should be interpreted as having meanings that are consistent with their meanings in the context of the relevant art and will not be interpreted in an idealized or overly formal sense unless expressly so defined herein.

Hereinafter, preferred embodiments of the present disclosure will be described in detail with reference to the accompanying drawings.

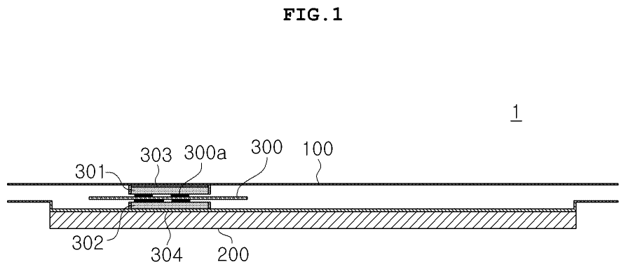

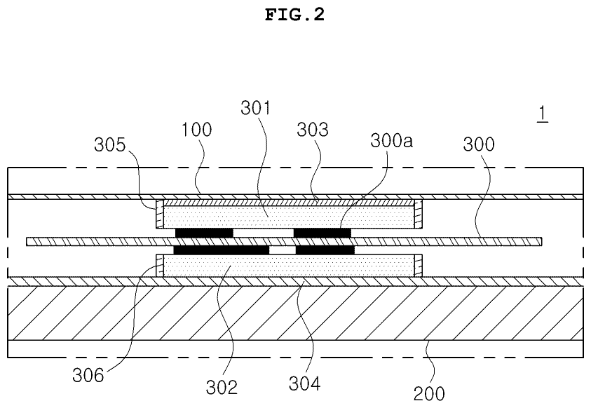

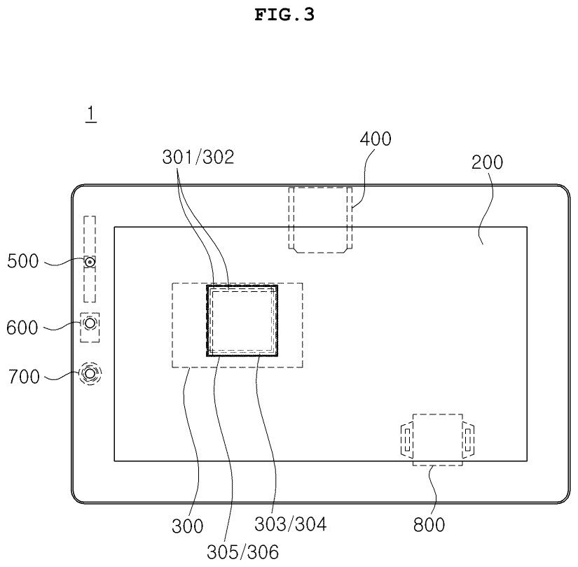

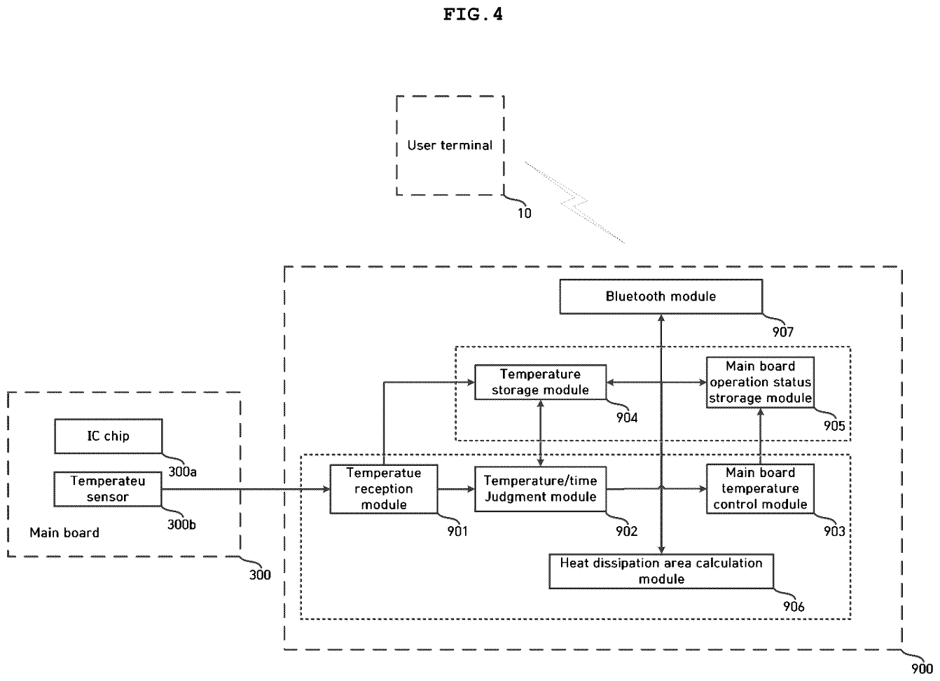

FIG. 1 is a side view of of a display device with thermal pad according to one embodiment of the present disclosure, FIG. 2 is a side perspective view of a display device with thermal pad according to one embodiment of the present disclosure, FIG. 3 is an interior perspective view of a display device with thermal pad according to one embodiment of the present disclosure, FIG. 4 is a block configuration diagram of a sub-board according to one embodiment of the present disclosure.

Referring to FIGS. 1 to 4, a display device 1 with a thermal pad according to one embodiment of the present disclosure may be configured to include a housing 100, a touchscreen panel 200, a main board 300, a GPS sensor 400, a camera sensor 500, a condenser microphone 600, a human body detection sensor 700, a gyro sensor 800, a sub-board 900.

The display device 1 may be configured to be attached to the wall of the elevator and output advertisements, and necessary information and the like.

Hereafter, detailed configuration is described.

The housing 100 may be configured to constitute an enclosure of the display device 1. The housing 100 may be composed of a metal material.

The touchscreen panel 200 may be configured to output contents. Here, the contents may be advertising contents or informational contents, and may include information about what to do in an emergency situation.

The main board 300 may be configured to have at least one or more IC chips 300a on a first side and at least one or more IC chips 300a on a second side. The IC chips 300a may include any of a CPU, memory, ROM, and the like.

The main board 300 may be configured to include a first thermal pad 301, a second thermal pad 302, a first aluminum plate 303, a second aluminum plate 304, a first insulating band 305, and a second insulating band 306.

Hereafter, detailed configuration is described.

The first thermal pad 301 may be configured to be attached to at least one IC chip 300a provided on a first side of the main board 300.

Here, the first thermal pad 301 may be configured to be formed with a width that allows it to be in contact with all one side of the at least one IC chip 300a provided on the first side of the main board 300.

The second thermal pad 302 may be configured to be attached to the at least one IC chip 300a provided on the second side of the main board 300.

The second thermal pad 302 may be configured to be formed with a width that allows it to be in contact with all one side oe the at least one IC chip 300a provided on the second side of the main board 300.

The first thermal pad 301 and the second thermal pad 302 may be composed of a silicon material having a thermal conductivity of 6 W/mk. The first thermal pad 301 and the second thermal pad 302 can easily conduct heat generated by the IC chip 300a due to their high thermal conductivity.

The first aluminum plate 303 may be configured to be provided on the first thermal pad 301.

The first aluminum plate 303 may be configured to be in contact with a specific area on the back of the enclosure of the housing 100.

The second aluminum plate 304 may be configured to be provided on the second thermal pad 302.

Here, the second aluminum plate 304 may be configured to be in contact with one side of the touchscreen panel 200.

The first aluminum plate 303 and the second aluminum plate 304 may be configured to have a thermal conductivity of 7 W/mk. The first aluminum plate 303 and the second aluminum plate 304 can transfer heat from the first thermal pad 301 and heat from the second thermal pad 302 by their high conductivity.

The first insulating band 305 may be configured to wrap around each side perimeter of the first thermal pad 301 and the first aluminum plate 303.

The second insulating band 306 may be configured to wrap around each side perimeter of the second thermal pad 302 and the second aluminum plate 304.

The first insulating band 305 and the second insulating band 306 may function to allow heat from the first thermal pad 301 and the second thermal pad 302, respectively, to be conducted to the first aluminum plate 303 and the second aluminum plate 304, respectively, without loss.

The touchscreen panel 200 may be formed with a thickness of 10 mm, the main board 300 may be formed with a thickness of 1.6 mm, the first thermal pad 301 and the second thermal pad 302 may be formed with a thickness of 4 mm each, and the first aluminum plate 303 and the second aluminum plate 304 may be formed with a thickness of 1.2 mm each.

The GPS sensor 400 may be configured to detect a GPS signal.

The camera sensor 500 may be configured to photograph a subject in front of the elevator.

The condenser microphone 600 may be configured to pick up voices or sounds within the elevator.

The human body detection sensor 700 may be configured to detect the presence of a human body in the elevator. The human body detection sensor 700 may comprise an infrared sensor, a lidar sensor, or the like.

The gyro sensor 800 may be configured to detect elevator ascent/descent.

The main board 300 may be configured to output predetermined content via the touchscreen panel 200 when a person is detected in the elevator by the camera sensor 500, the condenser microphone 600, and the human body detection sensor 700. The main board 300 may be configured to only output contents when a person is present, as the IC chip 300a may overheat and it is pointless to output contents when there is no person present.

The main board 300 may further comprise a temperature sensor 300a.

The temperature sensor 300a may be configured to directly measure the temperature of each IC chip 300a on the main board 300 and transmit the measured temperature to the sub-board 900 in real time.

The sub-board 900 may be configured to receive the temperature from the temperature sensor 300a in real time, and to control the operation of the main board 300 in real time based on the real-time received temperature.

The sub-board 900 may be configured to include a temperature reception module 901, a temperature/time judgment module 902, a main board temperature control module 903, a temperature storage module 904, a main board operation state storage module 905, a heat dissipation area calculation module 906, and a bluetooth module 907.

Here, the temperature reception module 901, the temperature/time judgment module 902, the main board temperature control module 903, and the heat dissipation area calculation module 906 may be configured to be operated by an IC chip such as a CPU or ROM, and the temperature storage module 904 and the main board operation state storage module 905 may be implemented on a memory chip.

Hereafter, detailed configuration is described.

The temperature reception module 901 may be configured to receive a temperature from the temperature sensor 300a in real time.

The temperature/time judgment module 902 may be configured to determine whether the real-time received temperature is above a predetermined threshold and lasts for a predetermined time.

The main board temperature control module 903 may be configured to stop or limit operation of the IC chip 300a on the main board 300 such that the temperature is maintained below the predetermined threshold, and to maintain operation of the IC chip 300a on the main board 300 while the temperature is maintained below the predetermined threshold, if the temperature above the predetermined threshold persists for more than a predetermined time as a result of the judgment of the temperature/time judgment module.

The main board temperature control module 903 may be configured to cause the main board 300 to limit the output of the touchscreen panel 200.

For example, if the temperature of the IC chip 300a remains in an overheated state for an extended period of time, it can be controlled to remain in a sleep state without outputting content when a person enters the elevator.

And the main board temperature control module 903 may be configured to maintain the operation of the camera sensor 500, the condenser microphone 600, and the human body detection sensor 700 in the event of restricting the operation of the main board, and to maintain the ability to determine a predetermined dangerous situation based on the operation of the camera sensor 500, the condenser microphone 600, and the human body detection sensor 700. For example, if a situation occurs in the elevator where a person falls down, fights, or is trapped due to an elevator malfunction, the IC chip 300a may be configured to cause the camera sensor 500, condenser microphone 600, and human body detection sensor 700 to detect the dangerous situation even if the IC chip 300a is in an overheated state, thereby causing the main board 300 to issue necessary emergency action instructions and output the necessary content.

The temperature storage module 904 may be configured to cumulatively store the temperature received from the temperature reception module 901 in real time.

The main board operation state storage module 905 may be configured to accumulatively store the real-time operation halt state or operation limit state of the IC chip 300a on the main board 300 by the main board temperature control module 903.

The heat dissipation area calculation module 906 may be configured to calculate the area of the first thermal pad 301 and the second thermal pad 302, respectively, based on the temperature accumulatively stored in the temperature storage module 904 and the operation halt state or operation limit state accumulatively recorded in the main board operation statue storage module 905.

If the elevator is frequently carried by people, the display device (1) is more likely to overheat due to the frequent motion of the display device (1), while if the elevator is only occasionally carried by people, the display device (1) is less likely to overheat due to the low number of motions of the display device (1).

Therefore, the operating environment of the display device 1 differs for each elevator, and the necessary heat dissipation means need to be optimized differently. In other words, the display device 1 that is likely to overheat requires a thicker or larger thickness or area of the thermal pad 301, 302 or aluminum plate 303, 304.

The thermal conductivity may be measured as the amount of heat transferred in 1 hour when there is a temperature difference of 1° C. on both surfaces of a material having a thickness of 1 m and an area of 1 m². Accordingly, the unit of thermal conductivity is expressed in kcal/mh° C., where 1 W/mK is equivalent to 0.86 Kcal/mh° C.

The heat dissipation area calculation module 906 may calculate the required area of the thermal pads 301, 302 or aluminum plates 303, 304 based on the cumulative temperature history over time relative to the intrinsic thermal conductivity of the thermal pads 301, 302 and the intrinsic thermal conductivity of the aluminum plates 303, 304. If the thickness is difficult to control depending on the arrangement of each configuration in the internal space, the area can only be increased.

The bluetooth module 907 may be configured to transmit the temperature accumulatively stored in the temperature storage module 904, the operation halt state or operation limit state accumulatively recorded in the main board operation state storage module 905, and the heat dissipation area calculated in the heat dissipation area calculation module 906 to the user terminal 10.

Using the heat dissipation area received by the user terminal 10, the user may take steps to increase the area of the thermal pads 301, 302 and the aluminum plates 303, 304 to the extent required for the corresponding display device 1.

Although the present disclosure was described above with reference to exemplary embodiments, it should be understood that the present disclosure may be changed and modified in various ways by those skilled in the art, without departing from the spirit and scope of the present disclosure described in claims.

1. Display device with thermal pad, the display device comprising:
a main board having at least one IC chip on a first side;
a thermal pad having a first thermal pad attached to the at least one IC chip provided on the first side of the main board.

2. The display device of claim 1, wherein the main board is configured to have at least one IC chip on a second side.

3. The display device of claim 2, further comprising a second thermal pad attached to the at least one IC chip provided on the second side of the main board.
